(19) United States
(12) Patent Application Publication
(10) Pub. No.: US 2024/0426922 A1
(43) Pub. Date: Dec. 26, 2024

(54) METHOD FOR DETERMINING AT LEAST ONE ESTIMATED OPERATING PARAMETER OF A BATTERY

(71) Applicant: Lisa Dräxlmaier GmbH, Vilsbiburg (DE)

(72) Inventor: Dirk LEHMKUHL, Landshut (DE)

(73) Assignee: Lisa Dräxlmaier GmbH, Vilsbiburg (DE)

(21) Appl. No.: 18/828,866

(22) Filed: Sep. 9, 2024

Related U.S. Application Data
(63) Continuation of application No. PCT/EP2023/053040, filed on Feb. 8, 2023.

(30) Foreign Application Priority Data
Mar. 9, 2022 (DE) 102022105481.0

(51) Int. Cl. G01R 31/367; G01R 31/387

(52) U.S. Cl. CPC G01R 31/367; G01R 31/387

(57) ABSTRACT

A method for determining at least one estimated operating parameter of a battery including receiving at least one measured operating parameter of the battery and determining the at least one estimated operating parameter from the at least one measured operating parameter using a mathematical battery model based on an equivalent circuit of the battery having at least one RC element. The battery model defines a relationship between the battery voltage applied to the battery and a battery current flowing through the battery in dependence of model parameters including at least one time constant and/or at least one electrical resistance with respect to the equivalent circuit. The battery model takes into account an n-th power of a Taylor series expansion of the at least one time constant and/or the at least one electrical resistance around an operating point of the battery.

### CROSS-REFERENCE TO RELATED APPLICATIONS

This application is a continuation of International Application No. PCT/EP2023/053040, filed on Feb. 8, 2023, which claims priority to and the benefit of DE 10 2022 105 481.0 filed on Mar. 9, 2022. The disclosures of the above applications are incorporated herein by reference.

### FIELD

The present disclosure relates to a computer-implemented method for determining at least one estimated operating parameter of a battery.

### BACKGROUND

The statements in this section merely provide background information related to the present disclosure and may not constitute prior art.

In order to increase the service life of a battery, for example, a drive battery for an electric vehicle, a current maximum performance of the battery and/or its allowable operating range should be known at all times. For this purpose, the dynamic behavior of the battery can be represented in a multidimensional state space, which can be parametrized by means of different state values such as, for example, temperature, state of charge, and/or amperage.

The mathematical modeling of the battery can be based, for example, on an equivalent circuit of the battery, which can comprise one or more RC elements. The model parameters of such a model can be defined in terms of various operating points of the battery, for example, specific charge levels and/or temperatures. Time constants and specific resistances in the neighborhood of an operating point are usually adopted as constant. This adoption makes possible sufficiently precise predictions for relatively short prediction periods and/or relatively low current amplitudes. In particular with a sporty driving style, it is important, however, that precise predictions can be made with respect to the performance of the battery even for longer prediction periods and/or higher current amplitudes.

### SUMMARY

This section provides a general summary of the disclosure and is not a comprehensive disclosure of its full scope or all of its features.

The present disclosure improves the estimation of operating parameters of a battery. The present disclosure provides a method, which improves the estimation with reference to precision and/or processing efficiency with longer prediction periods and/or higher current amplitudes. The present disclosure further relates to a data processing device, a battery management system, a battery, a computer program, and a computer-readable medium for the implementing the method.

A first aspect of the present disclosure relates to a computer-implemented method for determining at least one estimated operating parameter of a battery. The method comprises at least the following steps: receiving at least one measured operating parameter of the battery; and determining the least one estimated operating parameter from the at least one measured operating parameter using a mathematical battery model based on an equivalent circuit, comprising at least one RC element of the battery, in which the battery model defines a relationship between a battery voltage applied to the battery and a battery current flowing through the battery depending on model parameters, which comprise at least one time constant and/or at least one electrical resistance with reference to the equivalent circuit, wherein the battery model takes into account an n-th power of a Taylor series expansion of the at least one time constant and/or the at least one electrical resistance around an operating point of the battery, in which n>0.

In other words, the respective model parameter in the neighborhood of the operating environment can be approximated by a polynomial of n-th degree with n>0. The model parameter in the neighborhood of the operating point can consequently be, for example, linearized (instead of, as in the past, being assumed to be approximately constant). This makes possible improved estimates with high battery currents and/or long prediction periods, for example, of 10 s or longer, in particular 20 s or longer.

An analytical solution of the battery model, that is, the differential equation system that simulates the equivalent circuit, is nevertheless made possible, which improves the processing efficiency and/or reduces the desired storage.

The method can be implemented automatically by means of a processor.

The battery can comprise one or more galvanic battery cells that can be connected to each other in series and/or in parallel in order to form the battery.

The battery model can be time-variant, that is, the model parameters can be continuously updated in the operation of the battery, for example, in order to take aging effects into consideration. The dynamic behavior of the battery usually changes with increasing age of the battery. In order to take this into account, a suitable parameter estimator can be provided for adapting the model parameters, for example, an extended Kalman filter. A time-invariant battery model would, however, also be conceivable.

The electrical resistance can be, for example, an ohmic resistance, also called (equivalent) series resistance, or a resistance of the RC element. The time constant can, at the same time, be equal to a product of the resistance and the capacitance of the RC element.

The measured operating parameter or the measured operating parameters can have been determined by a sensor system, which can be determined, for example, by means of a sensor system, which can be part of the battery and/or of a battery management system for monitoring and/or controlling the battery. The sensor system can comprise, for example, one or more current, voltage, and/or temperature sensors.

Examples for possible measured and/or estimated operating parameters are an electrical voltage (with or without load) applied to the terminals of the battery, an electrical battery current flowing through the battery, or a temperature of the battery.

Further examples of possible estimated operating parameters are a state of charge SOC (state of charge), a state of health SOH (state of health), a state of power SOP (state of power), an upper or lower voltage limit, an upper or lower temperature limit, an upper or lower current limit, a charging capacity, a discharging capacity, an available energy, or a retrievable energy of the battery.

The state of charge SOC can be understood as a fill level of the battery in percentage, wherein a state of charge of 100% can correspond to a fully charged battery. The state of charge can be determined, for example, by integration of the (measured) battery current.

The state of health SOH can be a parameter that quantifies the ability of the battery for making available a demanded power in comparison to the battery in the new state.

The state of power SOP can be a parameter that quantifies the ability of the battery for making available a currently demanded power in the current state, that is, its performance. The state of power SOP can depend on the state of charge SOC, the state of health SOH, and the temperature of the battery.

The operating point can be defined, for example, by means of the state of charge and/or the temperature of the battery and/or a temporal course of at least one of these two values.

The model parameters can have been determined, for example, for each operating point from a quantity of predetermined operating points, or are continuously determined, for example for states of charge of 0% to 100%, which can follow one another with a specific increment (for example, 1%, 5%, or 10%).

Further examples of possible model parameters are an open circuit voltage of the battery, the capacitance of the RC element and/or the battery, or a voltage drop over the capacitance of the RC element.

The battery model can also be based on two or more than two RC elements that can be connected to each other, for example, in series. This can indeed improve the precision, but can, on the other hand, significantly increase the resource consumption. If the aging of the battery is not taken into account, then the approach presented herein can also be advantageously applied to such an equivalent circuit model with a plurality of RC elements. An improvement of the range of validity and/or the precision of the prediction can thus be achieved in comparison to a comparable conventional equivalent circuit model.

Depending on the number of RC elements, the model parameters can also comprise a plurality of time constants and/or a plurality of electrical resistances whose n-th powers of the Taylor series expansion around the operating point can be taken into account by the battery model as the expansion center (with n>0) in the same or a similar manner as with only one RC element.

A battery management system and the software found thereon are desired to estimate a balancing and a current state of the battery and carry out a performance prediction for different time periods, for example, “short,” “medium,” and “long.” The performance prediction is desired in order to enable the wish of a driver, for example, if the driver actuates the gas pedal. With very low states of charge, it should be provided that the battery voltage does not fall below a specific voltage limit when the predicted power is released. For this purpose, a battery model based on an equivalent circuit comprising one or several RC elements can be implemented in the software of the battery management system.

The accuracy of the battery model should be just as good for average and long prediction times as for short prediction times, especially with great discharge currents. This can be the case, for example, during sporty driving. The approach described herein now makes possible a very accurate performance prediction also for average and long prediction times. Other applications are possible in addition to the performance prediction. For example, the approach presented here can also be transferred to higher battery or equivalent circuit models and/or to improve a Kalman filter or other parameter estimators.

An equivalent circuit with a single RC element can be described by means of a system of two equations of the first order. There is a special analytical solution for the differential equations that can be used to find the fit function. By comparing the values of the fit function to measured values can be produced a correspondingly improved set of parameters.

Specific assumptions about the dependency of the parameters were made until now for this analytical solution. Specific limitations with reference to the height and duration of the current loads were additionally applied in order to be able to compare the values of the analytical solution to the measured values. The validity range of the resulting fully parametrized battery model with predetermined accuracy is also restricted. Exceeding the validity range would thus have as a consequence a lower accuracy. In one example the prior assumptions that were usually made during the deduction of the analytical solution are at least in part no longer taken into consideration.

Expressed more simply, the approach presented here is based on a mathematical battery model which falls between an equivalent circuit model with only one RC element (also called “1 RC model”) and an equivalent circuit model with two RC elements (also called “2 RC model”) with respect to validity range and precision. A parameter estimator for the (continuous) estimation of the model parameters, for example, for taking into account the aging of the battery, can thus have a significantly lower complexity than with standard 2 RC models. The desired hardware of a parameter estimator simplified in this manner are approximately comparable to those of a standard 1 RC model. The time horizon of the performance prediction is therefore also greater, that is, the available performance of the battery can be predicted farther out with the same precision.

The available memory (RAM) and the available capacity of the CPU of a battery management system can thus be used more efficiently, which means that additional (and more complex) algorithms can be implemented thereon without significant hardware changes. Under some circumstances, the efficiency can be improved so much that even lower performance and correspondingly cheaper hardware components could be used without performance losses.

A method such as this makes possible, for example, an improved battery state recognition in electric vehicles, whereby a gentler operation of the battery over its service life can be provided.

A second aspect of the present disclosure relates to a data processing device with a processor configured for implementing the method described above and below. The data processing device can comprise hardware and/or software modules. In addition to the processor, the data processing device can comprise a memory and data communications interfaces for data communication with peripheral devices. The data processing device can be, for example, a controller of a battery management system, a control unit of a vehicle, a PC, server, laptop, or mobile device in the form of a smartphone or tablet. Under “vehicle” can be understood a vehicle equipped with an electric drive, for example, an automobile, truck, bus, motorcycle, or autonomously moving robots.

The features of the method can also be interpreted as features of the data processing device and vice versa.

A third aspect of the present disclosure relates to a battery management system comprising a sensor system for determining at least one measured operating parameter of a battery and a data processing device, as was described above and will be described below. The sensor system can be arranged, for example, in and/or on a housing of the battery.

A fourth aspect of the present disclosure relates to a battery, especially a lithium-ion battery, for example, a battery for supplying an electric drive of an electric vehicle with electric energy. The battery comprises the data processing device described above and below, or the battery management system described above and below.

Further aspects of the present disclosure relate to a computer program and a computer-readable medium, on which the computer program is stored.

The computer program comprises commands that cause a processor to implement the method described above and below during the implementation of the computer program by means of the processor.

The computer-readable medium can be a volatile or non-volatile data memory. For example, the computer-readable medium can be a hard drive, a USB storage device, a RAM, ROM, EPROM, or flash memory. The computer-readable medium can also be a data communication network that makes it possible to download a program code such as, for example, the internet or a data cloud (cloud).

Features of the method described above and below can also be understood as features of the computer program and/or of the computer-readable medium and vice versa.

It is possible that the at least one measured operating parameter is received in a plurality of successive time steps. This can be understood in such a way that in each time step at least one measured value is received for the same measured operating parameter, or at least one measured value is received for different measured operating parameters. Here, the at least one estimated operating parameter can be determined in a current time step from the measured values of various time steps, for example, from the measured value or values of the current time step and the time step immediately preceding the current time step. For example, the at least one estimated operating parameter can be determined in the current time step for at least one of the future time steps following the current time step.

The determination of the at least one estimated operating parameter can take place, for example, with the aid of a Kalman filter, in particular an extended Kalman filter, and/or a particle filter.

What has been stated above with reference to the determination of the estimated operating parameter or parameters can also apply in a corresponding manner to a (continuous) estimation of the model parameters.

According to one example, n=1. Expressed in other words, the battery model can take into account a linearization of the at least one time constant and/or of the at least one electrical resistance in the determination of the at least one estimated operating parameter. Experiments have shown that the predicted accuracy—in contrast to the conventional assumptions according to which only constant approximations of the time constant or the electrical resistance make possible an analytical solution—can be significantly improved in this manner without more computing resources being required for this purpose.

According to one example, the battery model can be defined by means of the following equation:

$${U}_{Cell} = {I}_{Cell} ( λ ( 1 - {e}^{- \frac{t}{τ ( SOC ( {t}_{0} ) , T ( t ) )}} ) + t ψ + η )$$

in which U_{Cell} is the battery voltage, I_{cell} is the battery current, τ is the time constant, SOC is a state of charge of the battery, T is a temperature of the battery, and λ, ψ, η are coefficients (the independent variable is the time t). For example, I_{Cell} can be constant. The linear term tψ is also clearly apparent in measurements for long pulse durations and high current amplitudes.

According to one example, at least one of the coefficients λ, ψ, η can be defined as the operating point in a manner depending on the n-th power of the Taylor series expansion of the at least one electrical resistance around the state of charge SOC(t₀). For example, each coefficient λ, ψ, η can be defined by means of a different coefficient equation. The state of charge SOC(t₀) can be a reference state of charge, for example, an initial state of charge of the battery, at a reference time point t₀, for example, an initial time point.

The coefficients can be determined experimentally and/or improved via a comparison to suitable measurements. It is possible that the coefficients are continuously updated in the operation of the battery, that is, online.

The coefficients can be stored, for example, in the form of lookup tables for different operating points. Alternatively, the coefficients can be calculated with mathematical functions (the coefficient equations).

According to one example the coefficient λ can be defined as the electrical resistance depending on the n-th power of the Taylor series expansion of a resistance of the RC element.

According to one example, the coefficient η can be defined as the electrical resistance depending on the n-th power of the Taylor series expansion of an ohmic resistance.

According to one example, the coefficient ψ can be defined in dependence of the n-th powers of the Taylor series expansion of various electrical resistances, for example, depending on a first n-th power of the ohmic resistance, and a second n-th power of the resistance of the RC element.

According to one example, at least one of the coefficients λ, ψ, η can additionally be defined in dependence of the battery current, that is, on its amount and/or direction. For example, each of the coefficients λ, ψ, η can be defined in dependence of the battery current. In contrast to the conventional assumptions, according to which the model parameters are assumed at least initially to be independent from the battery current, the precision of the method can be significantly improved in this way in particular with high battery currents.

According to one example, at least one of the coefficients λ, ψ, η can additionally be defined in dependence of the time constants. For example, the coefficient λ can additionally be defined in dependence of the time constants.

According to one example, at least one of the coefficients λ, ψ, η can additionally be defined in dependence of an n-th power of a Taylor series expansion of an open-circuit voltage of the battery around the state of charge SOC(t₀), in which n>0, in particular in which n=1. The open-circuit voltage can have been determined, for example, as an open-circuit voltage curve in dependence of the state of charge SOC. For example, the coefficients ψ and η can additionally be defined in dependence of the n-th power of the Taylor series expansion of the open-circuit voltage.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 illustrates a battery according to one example of the present disclosure;

FIG. 2 illustrates an equivalent circuit for use in a method according to one example of the present disclosure;

FIG. 3 illustrates an estimated voltage curve that was determined in a method according to one example of the present disclosure, in comparison to a measured voltage curve at a first operating point; and

FIG. 4 illustrates an estimated voltage curve that was determined in a method according to one example of the present disclosure, in comparison to a measured voltage curve at a second operating point.

The Figures are merely schematic and not true to scale. Identical reference numerals identify identical or functionally identical features in the various drawings.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

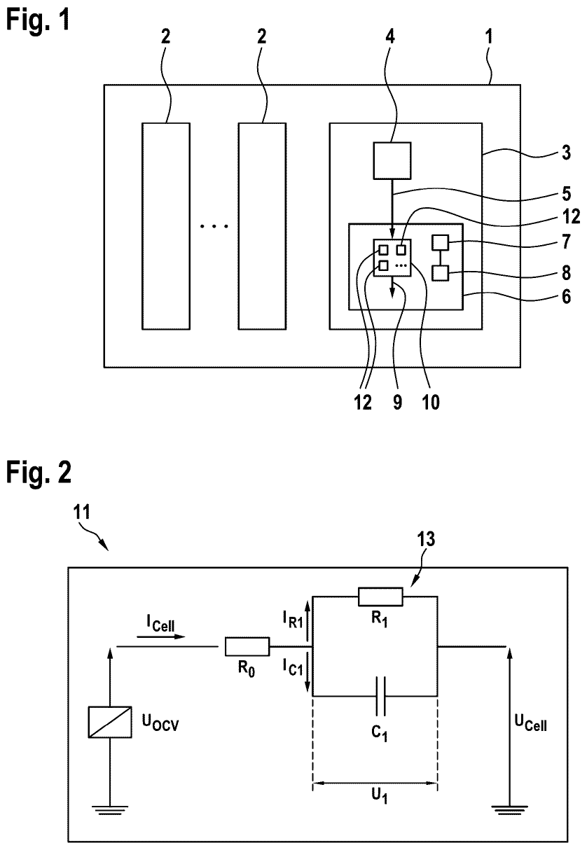

FIG. 1 shows a battery 1, for example, a lithium-ion battery, for supplying an electric drive of an electric vehicle with electrical energy. The battery 1 comprises a plurality of galvanic battery cells 2 that can be connected to one another in series and/or in parallel.

The battery 1 additionally comprises a battery management system 3 with a sensor system 4 for determining at least one measured operating parameter 5 of the battery 1 and a data processing device 6. The sensor system 4 can comprise, for example, one or more voltage, current, and/or temperature sensors that can be placed on and/or in a housing of the battery 1.

The data processing device 6, for example a microcontroller, comprises a processor 7 configured for determining at least one estimated operating parameter 9 from the measured operating parameter or parameters 5 by executing a computer program stored in a storage 8 with a method described in more detail below.

Here, the estimated operating parameter or parameters 9 are determined with the aid of a mathematical battery model 10 based on an equivalent circuit 11 of the battery 1 (see FIG. 2) and comprises a plurality of model parameters 12. The battery model 10 can especially be an equivalent circuit model with only one RC element 13 comprised of a resistance R₁ and a capacitance C₁, which makes the method particularly computationally efficient.

For example, the model parameters 12 can comprise one or more of the following magnitudes of the equivalent circuit 11: an ohmic resistance R₀, the resistance R₁, the capacitance C₁, a voltage drop U₁ over the capacitance C₁, and a time constant τ=R₁C₁.

In addition, a battery current I_{cell} flowing through the battery 1, a battery voltage U_{Cell} applied to the battery 1, an open-circuit voltage U_{OCV}, a current I_{C1} through the capacitance C₁, and a current I_{R1} through the resistance R₁ are drawn in FIG. 2.

For example, the battery current I_{cell} and a temperature T of the battery 1 can be received as measured operating parameters 5 in the data processing device 6, wherein the battery voltage U_{Cell} can be determined as the estimated operating parameter 9 by means of the data processing device 6.

Further examples of the estimated operating parameter 9 are a state of charge SOC, a state of health SOH, a state of power SOP, an upper or lower voltage limit, an upper or lower temperature limit, an upper or lower current limit, a charging capacity, a discharging capacity, an available energy, or a retrievable energy of the battery 1.

In order to determine the estimated operating parameter or parameters 9, the battery model 10 can take into account as expansion center (for example, in addition to a zeroth) a first power of a Taylor series expansion of the time constants τ and/or of at least one of the resistances R₀, R₁ around an operating point of the battery 1. Here, the operating point can be defined by the state of charge SOC and/or the temperature T. The values of R and C depend from the temperature T and the state of charge SOC.

The battery model 10 is described in more detail below.

According to the equivalent circuit 11, the simulated voltage response is:

$${U}_{Cell} ( SOC ( t ) , T ( t ) ) = {U}_{OCV} ( SOC ( t ) , T ( t ) ) + {R}_{0} ( SOC ( t ) , T ( t ) ) {I}_{Cell} ( t ) + {U}_{1} ( SOC ( t ) , T ( t ) ) \qquad ( 1 )$$

wherein U₁(t) is the solution of the differential equation.

$$τ ( SOC ( t ) , T ( t ) ) \frac{d}{dt} {U}_{1} ( t ) + {U}_{1} ( t ) = {R}_{1} ( SOC ( t ) , T ( t ) ) {I}_{Cell} ( t ) \frac{d}{dt} SOC ( t ) = \frac{{I}_{Cell} ( t )}{36 {C}_{Cell}} \qquad ( 2 )$$

wherein C_{Cell} is the capacitance of a battery cell 2 (the battery 1 comprises here 36 battery cells by way of example).

The values of R and C can be determined via a parameter identification. The parametrization can be carried out with the aid of a fit function determined by means of a specific analytical solution of the differential equations, for example, for pulse discharges and a rest period after a constant charging and/or discharging.

In addition to the parametrization, the fit function can also be used for other tasks, for example determining a limit current with predetermined state of charge, predetermined temperature, and predetermined limit voltage for the performance prediction in electric vehicles, developing a state observer or parameter estimator, developing an (extended) Kalman filter.

The following assumptions are made in the literature for the analytical solution of the differential equations.
1. The open-circuit voltage U_{OCV} is already well defined as function U_{OCV}(SOC,T) independent from the current direction.
2. All parameters are initially current-independent, both with respect to the current direction and with respect to the current amplitude.
3. The values R₀, R₁, C₁ and τ are constant in the vicinity of each operating point (SOC,T).

The values of U_{OCV}, R and C depend, among other things, from the state of charge SOC and thus, according to equation (1), explicitly from the current and on the time. Therefore, point 2 and point 3 are not to be considered as independent from each other. The greater the amplitude of the current is, the smaller the time should be chosen within which the values of R₀, R₁ and C₁ are assumed to be constant.

These assumptions, which only apply in the marginal case “pulse time approaches zero,” provide a parameter set, for example, for the operating point (SOC=50%, T=25° C.).

If the parameters for all operating points are fixed, which can correspond, for example, to SOC steps of 10%, the simulation results of the parametrized model can be compared to a further measurement, for example, from a driving cycle with longer pulse times. Depending on the result of the comparison, the parameters can then be manually and/or automatically improved with the aid of a further optimization algorithm. A parameter set is found, as a rule, with this method, which mathematically has the smallest squared error as local minimum.

Point 3 means, mathematically, that, for example, the Taylor series of R₁ with the expansion point (SOC,T), here with a constant temperature T, is discontinued after the first term:

$${T}_{0} {R}_{1} ( SOC ( t ) , SOC ( {t}_{0} ) ) = {R}_{1} ( SOC ( {t}_{0} ) ) \qquad ( 3 )$$

In order to increase the accuracy of the parametrization, not only U_{OCV} at the expansion point but also the slope of the function U_{OCV}SOC(t) can be taken into account with the fit function due to point 1. This does not affect the special analytical solution of the differential equation (2) for U₁(t).

Tests have shown that for a closed analytical solution of the differential equation, the assumptions according to point 2 and point 3 may be omitted. For this purpose, a further term is considered in the Taylor series, for example, of R₁:

$${T}_{1} {R}_{1} ( SOC ( t ) , SOC ( {t}_{0} ) ) = {R}_{1} ( SOC ( {t}_{0} ) ) + \frac{d}{dSOC} {R}_{1} ( SOC ) {\vert}_{SOC \to SOC ( {t}_{0} )} ( SOC ( t ) - SOC ( {t}_{0} ) ) \qquad ( 4 )$$

This can also be indicated as linearization of R₁ at the point SOC(t₀). If all Taylor series for R₀, R₁ and τ—for example, T₁ R₁(SOC(t),T) for R₁(SOC(t),T)—are used in the differential equation (2), then a new fit function can be found which contains five parameters instead of three parameters. However, the solution is quite complicated, for which reason it will not be discussed further here.

However, the second term of the Tayler series of τ(SOC(t),T(t)) is interesting. It could be explicitly confirmed with the new fit function that this function has a very low, negligible dependence on the state of charge for conventional battery cells.

The complete voltage response without the assumptions according to point 1 and point 2, and taking into account the simplification τ(SOC(t),T(t))=T(SOC(t₀),T(t)) is then:

$${U}_{Cell} = {I}_{Cell} ( λ ( 1 - {e}^{- \frac{t}{τ ( SOC ( {t}_{0} ) , T ( t ) )}} ) = t ψ + η ) \qquad ( 5 )$$

$$wherein :$$

$$Γ = \frac{{I}_{Cell}}{36 {C}_{Cell}}$$

$$λ = {R}_{1} ( SOC ( {t}_{0} ) ) + \frac{d}{dSOC} {R}_{1} ( SOC ) {\vert}_{SOC \to SOC ( {t}_{0} )} ( SOC ( {t}_{0} ) - τ Γ ) \qquad ( 6 )$$

$$ψ = ( \frac{d}{dSOC} {R}_{1} ( SOC ) {\vert}_{SOC \to SOC ( {t}_{0} )} + \frac{d}{dSOC} {R}_{0} ( SOC ) {\vert}_{SOC \to SOC ( {t}_{0} )} + \frac{1}{{I}_{Cell}} \frac{d}{dSOC} {U}_{OCV} ( SOC ) {\vert}_{SOC \to SOC ( {t}_{0} )} ) Γ \qquad ( 7 )$$

$$( 8 )$$

$$η = ( {R}_{0} ( SOC ( {t}_{0} ) ) + \frac{1}{{I}_{Cell}} {U}_{OCV} ( SOC ( {t}_{0} ) ) ) + ( \frac{d}{dSOC} {R}_{0} ( SOC ) {\vert}_{SOC \to SOC ( {t}_{0} )} + \frac{1}{{I}_{Cell}} \frac{d}{dSOC} {U}_{OCV} ( SOC ) {\vert}_{SOC \to SOC ( {t}_{0} )} ) SOC ( {t}_{0} )$$

and I_{cell} is a constant battery current.

The coefficients λ, ψ, η can be model parameters 12 which can be optimized, for example, by means of a comparison to measurements by means or the least squares method.

The new linear term tip, which is taken into account in the fit function, can also be clearly seen with pulse measurements for long pulse durations and high current amplitudes.

In principle, the additional determining of the parameter ψ does not represent any additional hurdle for the least squares method.

The term

d/dSOCU_{OCV}(SOC)|_{SOC→SOC(t}_{₀}₎
is sufficiently known due to point 1 (see above).

A linear equation thus results with the three equations (6), (7), (8) and two unknowns, namely the derivatives

d/dSOCR₁(SOC)|_{SOC→SOC(t}_{₀}₎

d/dSOCR₀(SOC)|_{SOC→SOC(t}_{₀}₎

These derivatives can be solved according to the rules of linear algebra.

The additional term tip can also be used in an extended Kalman filter. The found fit function thus makes possible a precise description of the linear behavior also for longer pulse durations with higher current amplitudes.

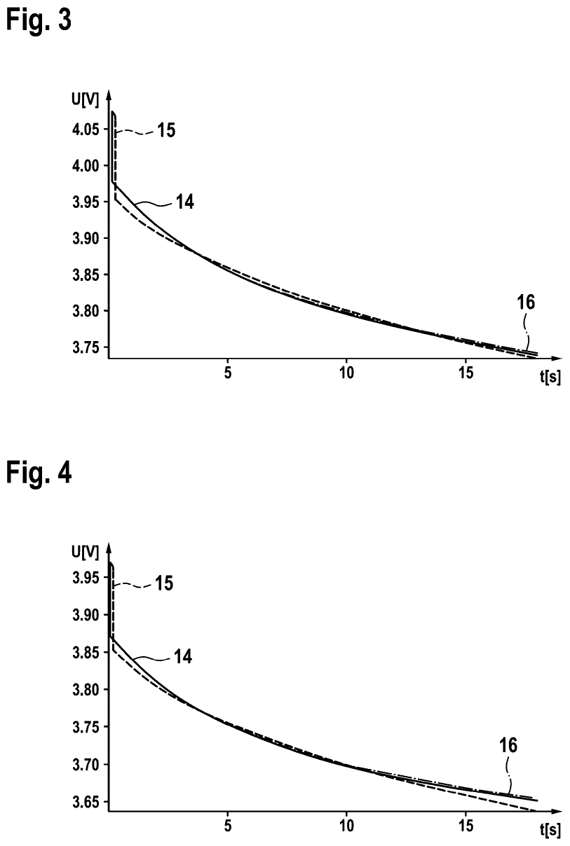

FIG. 3 shows a comparison between a voltage curve 14 estimated with the battery model 10 and a measured voltage course 15 for the same time period with a state of charge SOC from 90% and a temperature T of 25° C. For comparison purposes, a further voltage curve 16 which was estimated with a conventional 1 RC equivalent circuit model is additionally drawn in.

It is to be noted that the battery model 10 and the conventional 1 RC equivalent circuit model provide very similar results for short prediction times (t≈3 s) but the battery model 10 is closer to the measured voltage curve 15 for longer prediction times (t>>3 s).

FIG. 4 shows the three voltage curves 14, 15, 16 with a state of charge SOC of 80% and a temperature T of 25° C.

It can be seen in FIG. 3 and FIG. 4 that the results achieved with the battery model 10 can be clearly differentiated from the results achieved with the conventional 1 RC equivalent circuit model.

Since the devices and methods described in detail above are examples, the devices and methods can be modified to a great extent in the usual manner by the person skilled in the art without abandoning the scope of the present disclosure. Especially the mechanical arrangements and the proportions of the individual elements with respect to one another are to be considered as exemplary.

It is finally noted that terms such as “including,” “comprising,” etc. do not rule out other elements or steps, and that indefinite articles such as “a” or “an” do not exclude a plurality. It is furthermore noted that features or steps that were described with reference to one of the preceding examples can also be used in combination with features or steps that were described with reference to other preceding examples.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method for determining at least one estimated operating parameter of a battery, wherein the method comprises:
receiving at least one measured operating parameter of the battery; and
determining, by a processor, the at least one estimated operating parameter from the at least one measured operating parameter using a mathematical battery model based on an equivalent circuit of the battery comprising at least one RC element, the mathematical battery model defining a relationship between a battery voltage (U_{Cell}) applied to the battery and a battery current (I_{cell}) flowing through the battery in dependence of model parameters comprising at least one of at least one time constant and at least one electrical resistance (R₀, R₁) with respect to the equivalent circuit, the mathematical battery model takes into account an n-th power of a Taylor series expansion of at least one of the at least one time constant and the at least one electrical resistance (R₀, R₁) around an operating point of the battery, and n>0.

2. The method according to claim 1, wherein n=1.

3. The method according to claim 1,
wherein the mathematical battery model is defined by an equation:
$${U}_{Cell} = {I}_{Cell} ( λ ( 1 - {e}^{- \frac{t}{τ ( SOC ( {t}_{0} ) , T ( t ) )}} ) + t ψ + η )$$
wherein
U_{cell} is the battery voltage (U_{Cell}),
I_{Cell} is the battery current (I_{cell}),
τ is the at least one time constant,
SOC is a state of charge of the battery,
T is a temperature of the battery, and
λ, ψ, η are coefficients.

4. The method according to claim 3, wherein at least one of the coefficients λ, ψ, η is defined as an operating point in dependence of the n-th power of the Taylor series expansion of the at least one electrical resistance (R₀, R₁) around the state of charge SOC(t₀).

5. The method according to claim 4, wherein the coefficient λ is defined as the at least one electrical resistance (R₀, R₁) in dependence of the n-th power of the Taylor series expansion of a resistance (R₁) of the at least one RC element.

6. The method according to claim 4, wherein the coefficient q is defined as the at least one electrical resistance (R₀, R₁) in dependence of the n-th power of the Taylor series expansion of an ohmic resistance (R₀).

7. The method according to claim 4, wherein the coefficient ψ is defined in dependence of the n-th power of the Taylor series expansion of various electrical resistances (R₀, R₁).

8. The method according to claim 4 wherein at least one of the coefficients λ, ψ, η is defined in dependence of the battery current (I_{Cell}).

9. The method according to claim 4, wherein at least one of the coefficients λ, ψ, η is defined in dependence of the at least one time constant.

10. The method according to claim 4, wherein at least one of the coefficients λ, ψ, η is defined in dependence of an n-th power of a Taylor series expansion of an open circuit voltage (U_{OCV}) of the battery around the state of charge SOC(t₀).

11. A data processing device, comprising the processor configured to implement the method according to claim 1.

12. A battery management system, comprising:
a sensor system configured to determine at least one measured operating parameter of a battery; and
the data processing device according to claim 11.

13. A battery comprising the battery management system according to claim 12.

14. The battery according to claim 13, wherein the battery is a lithium ion battery.

15. A battery comprising
the data processing device according to claim 11.

16. The battery according to claim 15, wherein the battery is a lithium ion battery.

17. A computer program, comprising commands that cause the processor to implement the method according to claim 1 during execution of the computer program by the processor.

18. A computer-readable medium, on which the computer program according to claim 17 is stored.
